(19) United States
(12) Patent Application Publication
(10) Pub. No.: US 2009/0014048 A1
(43) Pub. Date: Jan. 15, 2009

(54) SOLAR COLLECTOR WITH HYDROPHILIC PHOTOCATALYTIC COATED PROTECTIVE PANE

(76) Inventor: GERALD D. BERANEK, LONE ROCK, WI (US)

Correspondence Address: MERCHANT & GOULD PC, P.O. BOX 2903, MINNEAPOLIS, MN, 55402-0903, US

(21) Appl. No.: 12/109,504

(22) Filed: Apr. 25, 2008

Related U.S. Application Data
(63) Continuation-in-part of application No. 11/740,707, filed on Apr. 26, 2007.

(51) Int. Cl. H01L 35/04; H01L 31/0216

(52) U.S. Cl. 136/206; 136/256; 136/246

(57) ABSTRACT

A solar collector which is illuminated by the sun through a glass panel wherein the glass panel is constructed of glass without low-e coatings with a first surface coating of a magnetron sputtered vapor deposition coating consisting primarily of titanium dioxide. The titanium dioxide achieves a hydrophilic photocatalytic surface to produce a solar collector which is self-cleaning for increased solar energy transmittance with less cleaning cost.

### CROSS REFERENCE TO RELATED APPLICATION

This application is a continuation-in-part to U.S. patent application Ser. No. 11/740,707, filed Apr. 26, 2007, which application is hereby incorporated by reference in its entirety.

### BACKGROUND OF THE INVENTION

The present invention relates to solar energy devices in general, and more particularly to the protective glass coverings of such devices through which solar radiation enters.

Solar radiation striking the earth's surface can be utilized in various fashions to provide for heating and electrical needs. Solar thermal collectors expose a working fluid to solar radiation, and then transport that liquid for use either directly or for heating some other fluid in a heat exchanger. Solar photovoltaic cells convert the solar radiation to electricity which is then either immediately used, stored in some fashion, or returned to the power grid. For purposes of this application, “solar collectors” encompasses both solar thermal collectors and solar photovoltaic cells. Typically solar collectors have a cover which allows solar radiation to pass through, but which blocks wind, precipitation, dust and debris from attaching to or degrading the solar device.

A conventional solar device cover will comprise a sheet of glass. The glass may or may not be transparent in the visible spectrum, but should be substantially transparent in the wavelengths being used by the solar device. Because of the protective function of the solar device cover, it will be exposed to contamination which can gradually obstruct the glass covering, resulting in a diminution of the solar energy passing through the cover to the solar device. To restore the performance of the solar device it is then necessary to periodically clean the glass covers, something that may be cumbersome, time consuming, and costly and potentially unsafe.

Various coatings have been applied to glass panels to reduce the obstruction occurring over time due to exposure to the elements. What is needed is a glass panel for a solar collector cover which contributes to optimal transmission of solar energy and which addresses the problem of dirt build-up thereon.

### SUMMARY OF THE INVENTION

The solar collector of this invention comprises an array of solar cells or fluid containing heat absorbing channels which are illuminated by the sun through a glass panel wherein the glass panel is constructed of thin high transmissive low iron (typically as Fe₂O₃) glass with a first surface titanium dioxide that can be in the form of a coating of a magnetron sputter vapor deposition coating consisting primarily of titanium dioxide. The titanium dioxide coating achieves a hydrophilic and photocatalytic surface. The hydrophilic surface has a contact angle of 25° or less, preferably 20° or less. The back surface is preferably not coated.

It is a feature of the present invention to provide a solar collector with improved collection efficiency in the face of obscuring dust or dirt on the collector's glass cover.

It is a further feature of the present invention to provide a glass cover for a solar cell array or a solar absorption box with lower maintenance costs.

Further objects, features and advantages of the invention will be apparent from the following detailed description when taken in conjunction with the accompanying drawings.

### BRIEF DESCRIPTION OF THE DRAWINGS

FIG. 1 is side elevational cross-sectional view of a solar cell array module and glass cover of this invention.

FIG. 2 is a side elevational cross-sectional view of a solar absorber and glass cover of this invention.

### DETAILED DESCRIPTION OF THE PREFERRED EMBODIMENT

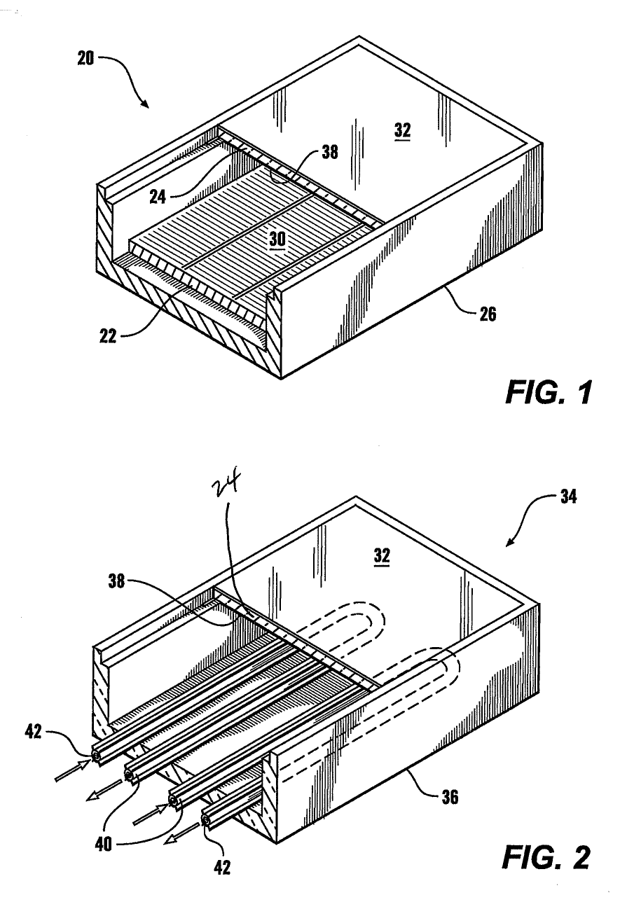

Referring more particularly to FIGS. 1-2, where like numbers refer to similar parts, a solar cell array module 20 is shown in FIG. 1. The solar cell array module 20 comprises a plurality of solar cells 22 positioned beneath a glass pane 24. The glass pane 24 together with an enclosure or box 26 protects the solar cells 22 from the environment. The glass pane 24 prevents rain, moisture and possibly corrosive elements from contacting the solar cells 22 which may corrode or short out in the presence of moisture. However to function, that is to generate power from the sun's rays, the glass pane is necessary in order to allow the sun's rays to reach the photoelectric surface 30 of the solar cells. The cost of solar cells, while continuing to decline, is still substantial. Therefore, to minimize the total cost and the number of solar cells needed it is important to maximize the amount of sunlight reaching the photoelectric surface 30 of the solar cells 22.

Although the module 20 may be fixed in place, to maximize the amount of sunlight falling on the solar cells the module 20 may be made be to track the sun, or may be adjusted seasonally. For example a solar cell array module located at 35 degrees north latitude such as in Albuquerque, N. Mex., will in the winter be oriented at an angle of about 60.5° from the horizontal and facing south. During the summer the optimum angle is closer to 8°. For latitudes at 45 North the optimal angle in the winter will be 67.5°, and 17° in the summer. Thus it is apparent that for solar collectors the orientation of the glass pane of the module 20 with respect to horizontal will often be closer to horizontal than to vertical, with the result that atmospheric dust may build up on the glass pane 24 blocking sunlight from reaching the solar cells 22 within the enclosure 26. Of course the build up of dust and dirt on the glass pane 24 of the module 20 could be dealt with by frequent washing, however this can involve considerable expense, especially when it is considered that solar collectors are often located on the roof of buildings or other relatively inaccessible locations.

Titanium dioxide coated windows have been developed which take advantage of the properties of titanium dioxide to achieve a hydrophilic and photocatalytic surface. The titanium dioxide may be in the anatase form, and in some cases can be doped with carbon. When windows employing such a titanium dioxide coating are exposed to ultraviolet light the surface becomes hydrophilic and photocatalytic so as to oxidize organic dirt, dust, and films which are in contact with the titanium dioxide coating. When rain or wash water is applied to the windows they are readily washed clean. Windows with titanium dioxide coating are normally supplied with other coatings, particularly low-E coatings which block ultraviolet and infrared rays in order to produce a window with less heat loss and less heat gain which is normally desirable in a window. Because the low-E coatings may give the glass an undesirable color, additional coatings are added in order to achieve a neutral color for aesthetic reasons. The glass pane 24 is preferably thin tempered glass, having a thickness of about 3-6 mm (⅛ to ¼ inches), and preferably of very clear glass such as can be achieved with a low iron content glass i.e., less than 0.1% iron oxide calculated on the basis of Fe₂O₃, such as is available, for example from Guardian Industries Corporation under the trademark Guardian UltraWhite™. Such a glass has visible light transmittance of 91% to 90% and a solar energy transmittance of 89 to 86% for glass thicknesses of 3 mm, or 6 mm (118 or ¼ inches) respectively. The glass is coated with a layer of less than 100 angstroms of titanium dioxide which is expected to reduce solar energy transmittance by less than 1% so that a suitable glass pane 24, will transmit 89 to 90% of visible light and have a solar energy transmittance of 85% to 88%. The titanium dioxide coating is illuminated by the sun through a panel wherein the panel is constructed of thin, high strength, tempered, high transmissive, low iron, photocatalytic coated, titanium dioxide, glass which produces a hydrophilic surface with a contact angle of 25 or less, preferably 20 or less. In one embodiment, the titanium dioxide layer can be deposited with the Magnetron Sputter Vapor Deposition (MSVD) process (also known as Magnetron Sputter Vacuum Deposition) (for purposes of this application, Magnetron Sputter Vapor Deposition will be used to include Magnetron Sputter Vacuum Deposition) which results in a smooth surface of controlled composition, which upon activation with ultraviolet light has a water droplet contact angle of 25° or less, preferably 200 or less, achieving even super hydrophilicity with a contact angle of near zero, i.e less than 2-3°. Other techniques for formation of titanium dioxide and other coatings are known. This low contact angle allows rainwater or wash water to sheet off the titanium dioxide pane surface 32.

The photocatalytic properties result in a gradual destruction of organic materials in contact with the titanium dioxide surface 32 in the presence of ultraviolet light. A suitable coating may be obtained from Cardinal Glass Industries, for example the titanium dioxide coating sold under the trademark Neat™ glass. With this applied coating, there is little or no affect on the solar transmittance or the solar reflectance. Conventional Cardinal window glass with this coating is not suitable for use with solar collectors because of its relatively low light transmission i.e., in addition to the photoactive hydrophilic titanium dioxide coating, other coatings, namely silver-based low-E coatings, are used which reduce total energy transmission through the glass. Moreover, silver-based low-E coated surfaces must be hermetically sealed to avoid oxidation, and thus are not suitable for the single pane of a solar collector. The glass pane of the present invention does not have low-E coatings. However the Cardinal Glass Neat™ coating, which contains metallic and nonmetallic layers but consists primarily of titanium dioxide, if applied to a suitable glass with high light transmissive properties provides a suitable glass for application in solar collectors. The benefit of the photoactive hydrophilic and photocatalytic titanium dioxide coated glass is that more light reaches the solar cells over time, because the glass pane is less obscured by soiling, due to the self-cleaning properties of the photocatalytic surface. The cost of maintenance of solar panels is also reduced because of the speed and ease of cleaning, and the relative infrequency of cleaning.

The Magnetron Sputter Vapor Deposition (MSVD) process is distinct from pyrolytic hydrophilic coatings inasmuch as the surface coating is substantially less rough, see for example the comparison on page 2 of Cardinal glass technical bulletin CG 05 of June 2006 which is incorporated herein by reference, which shows surface variations of over 20 nanometers on a short scale for a pyrolytic hydrophilic coating whereas the MSVD coating has few and lower peaks.

As shown in FIG. 2, a thermal solar collector module 34 has an insulating box 36 with a glass pane 24 with a titanium dioxide outer surface 32 and an uncoated inner surface 38. Inside the insulated box 36, thermal collecting tubes 40 or passageways are arranged to allow a fluid 42 moving through the passageways to gather solar heat which enters through the glass pane 24. As with the solar cell array module 20, the thermal solar collector module 34 employs the glass pane 24 to isolate and protect from the environment the solar collecting structures, such as the collecting tubes 40 and any light baffles and absorbers present. Furthermore, the glass panel acts to limit convective cooling of the interior of the insulated box 36. At the same time, the glass pane 24 provides over time greater solar incidence, and therefore greater solar energy because of the degrading of obscuring organic particles and film through the photocatalytic action of the titanium oxide coating. The photo active hydrophilic properties allow the ready removal by rainwater or washing of all contaminants which obscure the glass pane 24 outer surface 32.

It should be understood that because the glass pane 24 need not transmit images, the glass pane 24 may have a texture such that it is only translucent i.e., transmitting light but sufficiently diffuse as to prevent perception of distinct images, while still having the visible light transmittance and solar energy transmittance of clear glass.

It should be understood that the glass pane 24 of the device of FIG. 1 is not laminated to or directly affixed to the solar cells 22, but rather spaced a short distance from the solar cells, and that similarly in the device of FIG. 2, the glass pane 24 is not laminated or directly affixed to the collecting tubes 40.

It should be understood that the visible light and solar energy transmittance is defined with respect to low iron content glass such as is available for example from Guardian Industries Corporation under the trademark Guardian UltraWhite™ such that visible light transmittance of 91 to 90% and a solar energy transmittance of 89 to 86% pertain for glass thicknesses of 3 mm, or 6 mm (⅛ or ¼ inches) respectively.

It is understood that the invention is not limited to the particular construction and arrangement of parts herein illustrated and described, but embraces all such modified forms thereof as come within the scope of the following claims.

We claim:

1. A solar collector comprising:
means for collecting useful solar energy with an opening arranged to receive solar radiation; and
a glass pane, covering the opening, without a low-E coating with a pre-installation solar energy transmittance of greater than 85% and with an outer surface coated with a photocatalytic titanium dioxide coating of less than 100 angstroms in thickness, the titanium dioxide coating of the type which when exposed to ultraviolet light activates the outer surface to a hydrophilicity to the extent of having a water droplet contact angle of 0-25°; wherein the photocatalytic coating is capable to degrade organic matter in contact with the outer surface.

2. The solar collector of claim 1 wherein the means for collecting solar energy comprises collecting tubes containing a fluid.

3. The solar collector of claim 1 wherein the means for collecting solar energy comprises an array of solar cells.

4. The solar collector of claim 1 wherein the titanium dioxide coating is such that when activated by ultraviolet light the surface achieves a water droplet contact angle of less than 20°.

5. The solar collector of claim 1 wherein the glass pane solar energy transmittance is greater than 88%.

6. The solar collector of claim 1 wherein the glass pane solar energy transmittance is greater than 89%.

7. The solar collector of claim 1 wherein the titanium dioxide coating is applied by Magnetron Sputter Vapor Deposition

8. The solar collector of claim 1 wherein the glass pane is translucent tempered glass.

9. The solar collector of claim 1 wherein the glass pane is constructed of low iron glass of less than 0.1% iron oxide computed on Fe₂O₃.

10. A photovoltaic or thermal solar collector comprising:
an enclosure;
a solar cell array or a thermal collecting tube arrangement within the enclosure; and
the enclosure comprising a protective glass cover pane, the cover pane having a Magnetron Sputter Vapor Deposition coating comprising TiO₂, the coating less than 100 angstroms in thickness; wherein the coating is photocatalytic and hydrophilic and the cover pane has a solar transmittance of greater than 85 percent.
